(19) United States
(12) Patent Application Publication
(10) Pub. No.: US 2025/0192041 A1
(43) Pub. Date: Jun. 12, 2025

(54) WIRING STRUCTURES AND METHODS OF MANUFACTURING THE SAME

(71) Applicant: SAMSUNG ELECTRONICS CO., LTD, SUWON-SI (KR)

(72) Inventors: Seongcheon AHN, Suwon-si (KR); Kiil KIM, Suwon-si (KR); Changbea PARK, Suwon-si (KR); Jisoo OH, Suwon-si (KR); Seungmo HA, Suwon-si (KR)

(21) Appl. No.: 18/748,414

(22) Filed: Jun. 20, 2024

(30) Foreign Application Priority Data
Dec. 8, 2023 (KR) 10-2023-0177548

(51) Int. Cl. H01L 23/528

(52) U.S. Cl. CPC H01L 23/5283; H01L 23/528

(57) ABSTRACT

A wiring structure includes: a first wiring disposed on a substrate, wherein the first wiring includes a first extension portion that extends in a first direction and has a first width in a second direction, and a first expansion portion that is formed at a first end portion of end portions of the first extension portion and has a first maximum width, wherein the first maximum width is larger than the first width; and a second wiring disposed on the substrate, wherein the second wiring extends in the first direction and faces the first expansion portion of the first wiring, wherein a first end portion of end portions of the second wiring facing the first expansion portion has a second maximum width, wherein the second maximum width is substantially the same as the first maximum width.

### CROSS-REFERENCE TO RELATED APPLICATION

This application claims priority under 35 U.S.C. § 119 to Korean Patent Application No. 10-2023-0177548 filed on Dec. 8, 2023 in the Korean Intellectual Property Office, the disclosure of which is incorporated by reference herein in its entirety.

### TECHNICAL FIELD

Example embodiments of the present inventive concept relate to a wiring structure and a method of manufacturing the same.

### DISCUSSION OF THE RELATED ART

Self-aligned patterning processes such as SADP (Self-Aligned Double Patterning) and SAQP (Self-Aligned Quadruple Patterning) are currently under development and researched as a way to realize high resolution of fine patterns in methods of manufacturing wiring structures. The self-aligned patterning processes may be used, for example, in Back End of Line (BEOL) processes for forming wirings.

As semiconductor devices including the wiring structures are becoming increasingly integrated, pitch of wirings of BEOL are decreasing. Thus, a self-aligned pattern process to implement highly integrated wirings is currently under development.

### SUMMARY

According to example embodiments of the present inventive concept, a wiring structure includes: a first wiring disposed on a substrate, wherein the first wiring includes a first extension portion that extends in a first direction and has a first width in a second direction, and a first expansion portion that is formed at a first end portion of end portions, in the first direction, of the first extension portion and has a first maximum width in the second direction, wherein the first maximum width is larger than the first width, wherein the first direction is substantially parallel to an upper surface of the substrate, and the second direction is substantially parallel to the upper surface of the substrate and crosses the first direction; and a second wiring disposed on the substrate, wherein the second wiring extends in the first direction and faces the first expansion portion of the first wiring in the first direction, wherein a first end portion of end portions, in the first direction, of the second wiring facing the first expansion portion has a second maximum width in the second direction, wherein the second maximum width is substantially the same as the first maximum width.

According to example embodiments of the present inventive concept, a wiring structure includes: a wiring including: an extension portion disposed on a substrate, wherein the extension portion extends in a first direction, and the extension portion has a first width in a second direction, wherein the first direction is substantially parallel to an upper surface of the substrate, and the second direction is substantially parallel to the upper surface of the substrate and crosses the first direction; and expansion portions disposed on the substrate, wherein the expansion portions are disposed at both of end portions, in the first direction, of the extension portion, and the expansion portion has a first maximum width in the second direction, wherein the first maximum width is larger than the first width.

According to example embodiments of the present inventive concept, a wiring structure includes: first wirings disposed on a substrate, wherein the first wirings are spaced apart from each other in a second direction, wherein each of the first wirings includes a first extension portion that extends in a first direction and has a first width in the second direction, and a first expansion portion that is formed at a first end portion of end portions, in the first direction, of the first extension portion and has a first maximum width in the second direction, wherein the first maximum width is larger than the first width, wherein the first direction is substantially parallel to an upper surface of the substrate, and the second direction is substantially parallel to the upper surface of the substrate and crosses the first direction; second wirings disposed on the substrate, wherein the second wirings are spaced apart from each other in the second direction, wherein each of the second wirings extends in the first direction and faces the first expansion portion of the corresponding one of the first wirings in the first direction, and a first end portion of end portions, in the first direction, of at least one of the second wirings facing the first expansion portion of the corresponding one of the first wirings has a second maximum width in the second direction, wherein the second maximum width is substantially the same as the first maximum width; and third wirings disposed on the substrate, wherein each of the third wirings extends in the first direction between ones of the first and second wirings adjacent to each other in the second direction, wherein the third wirings are spaced apart from each other in the second direction, and wherein each of the third wirings has a third width in the second direction.

### BRIEF DESCRIPTION OF THE DRAWINGS

FIGS. 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, and 47 are plan views and cross-sectional views illustrating a method of manufacturing wiring structures according to example embodiments of the present inventive concept.

FIGS. 48 and 49 are cross-sectional views illustrating semiconductor devices according to comparative examples.

### DETAILED DESCRIPTION OF THE EMBODIMENTS

Hereinafter, first and second directions D1 and D2 are horizontal directions and are substantially parallel to an upper surface of a substrate. The first and second directions D1 and D2 may be substantially orthogonal to each other. Additionally, a direction substantially perpendicular to the upper surface of the substrate may be referred to as a third direction D3. Each of the first to third directions D1, D2 and D3 may represent not only a direction shown in the drawing, but also a reverse direction to the direction shown in the drawing. For example, the first direction D1 may represent an X-axis direction and a −X-axis direction.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the spirit and scope of the present invention.

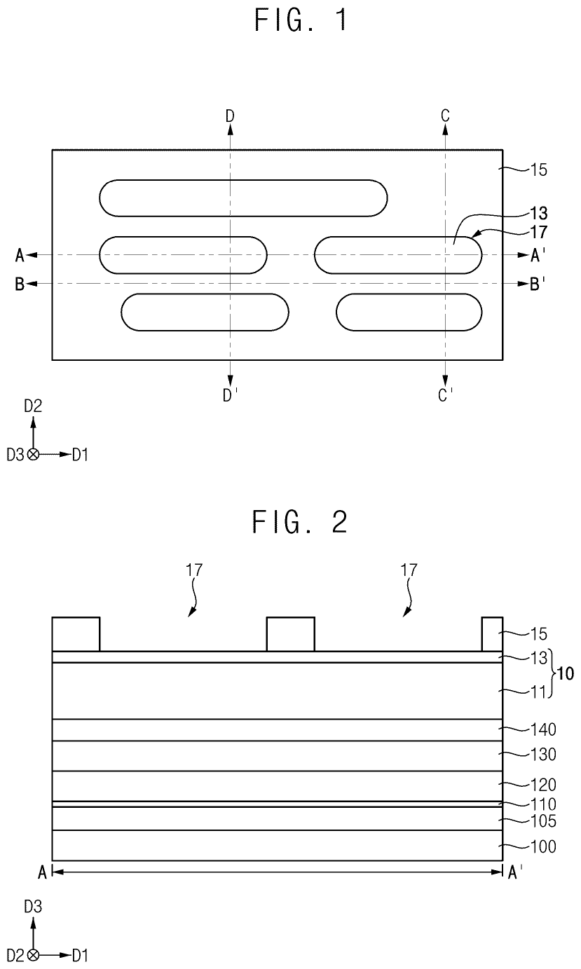

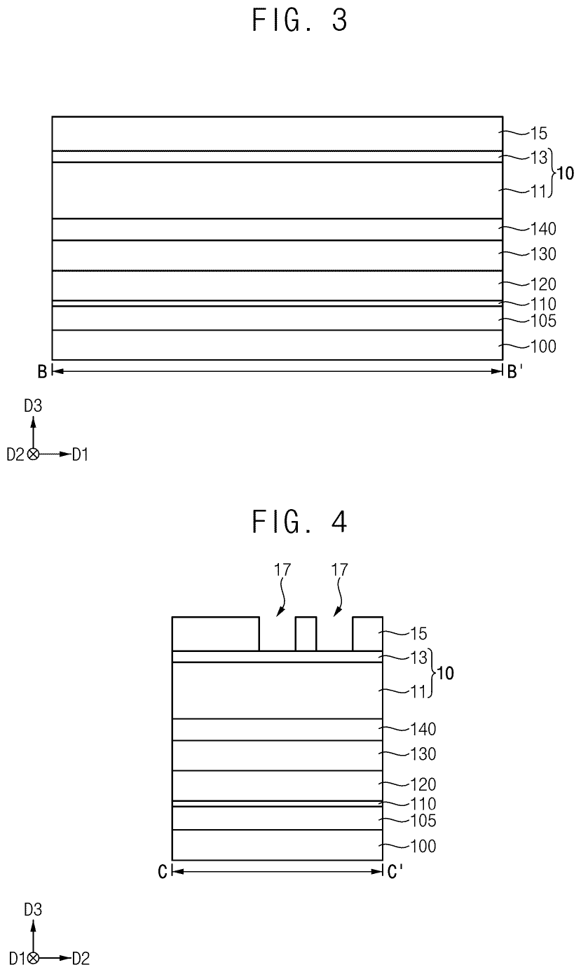

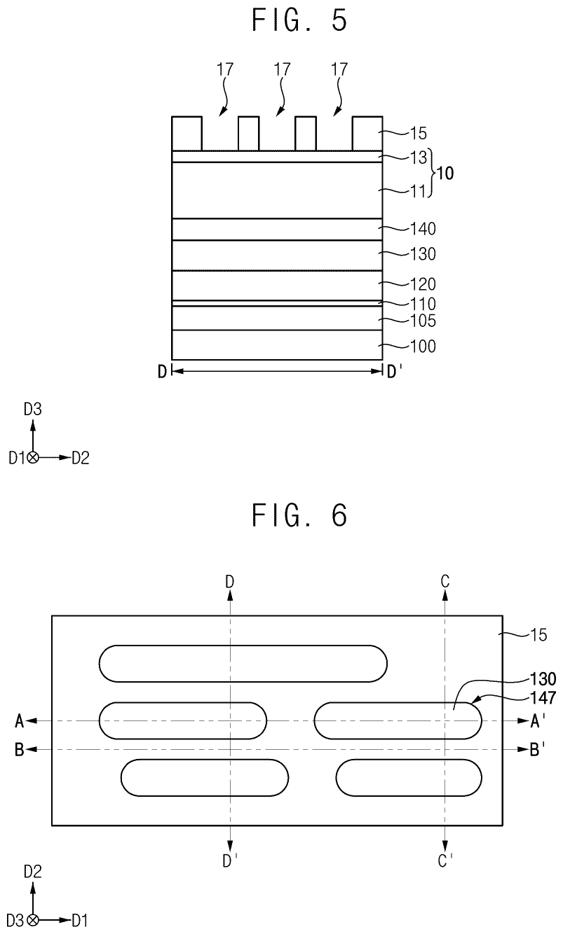

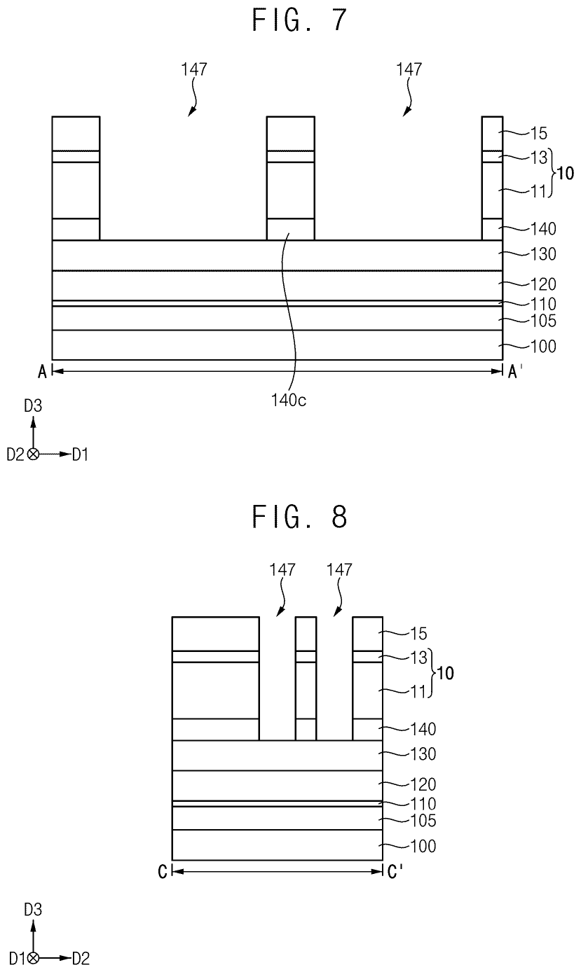

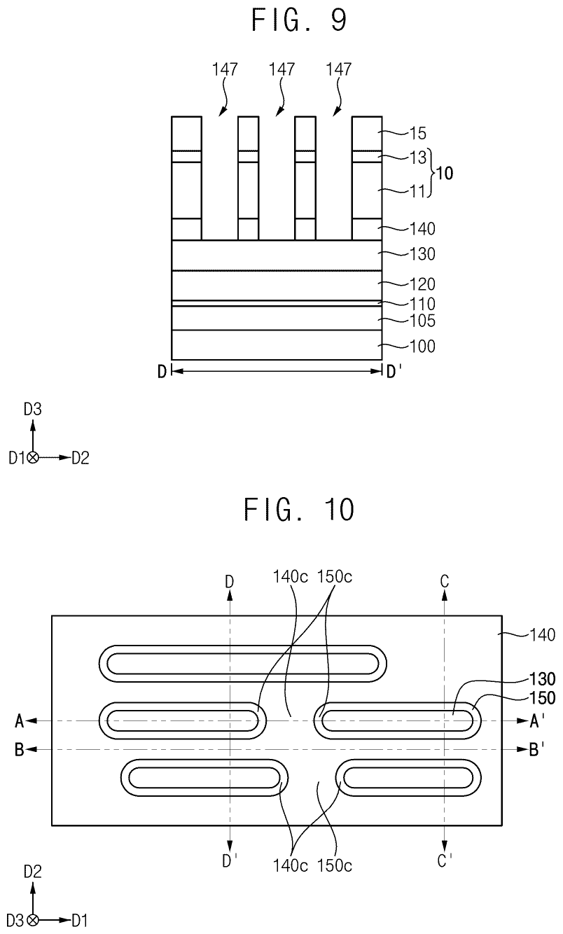

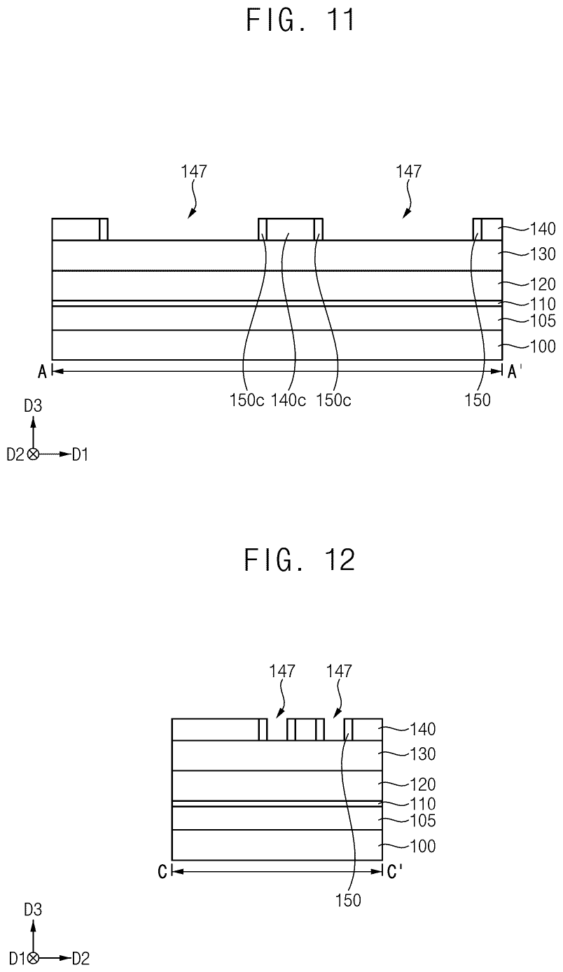

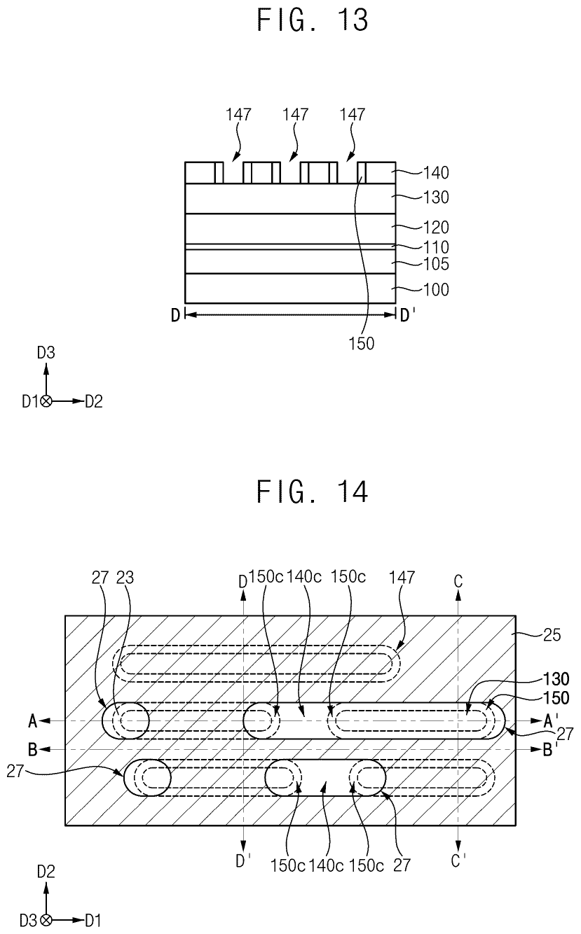

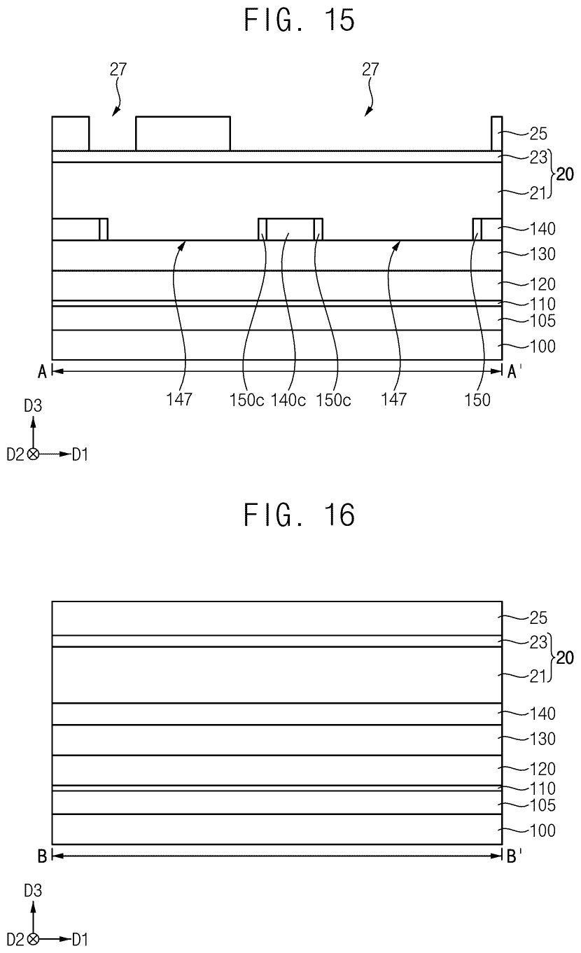

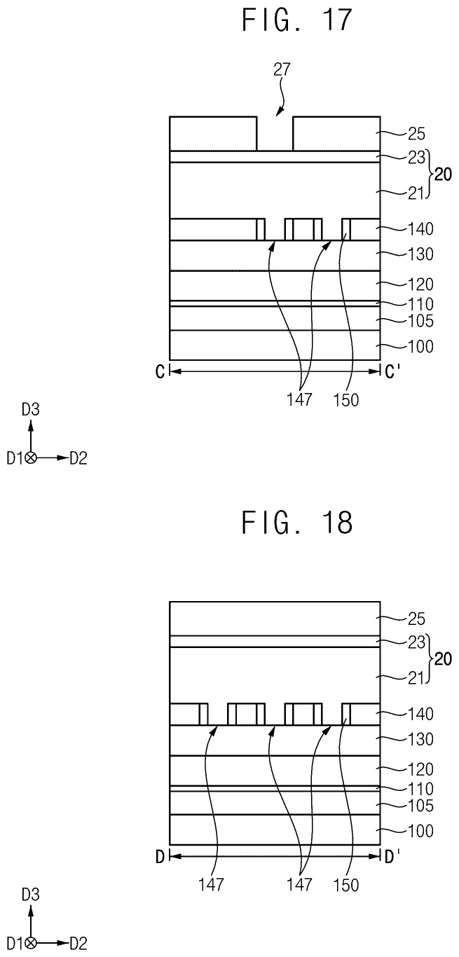

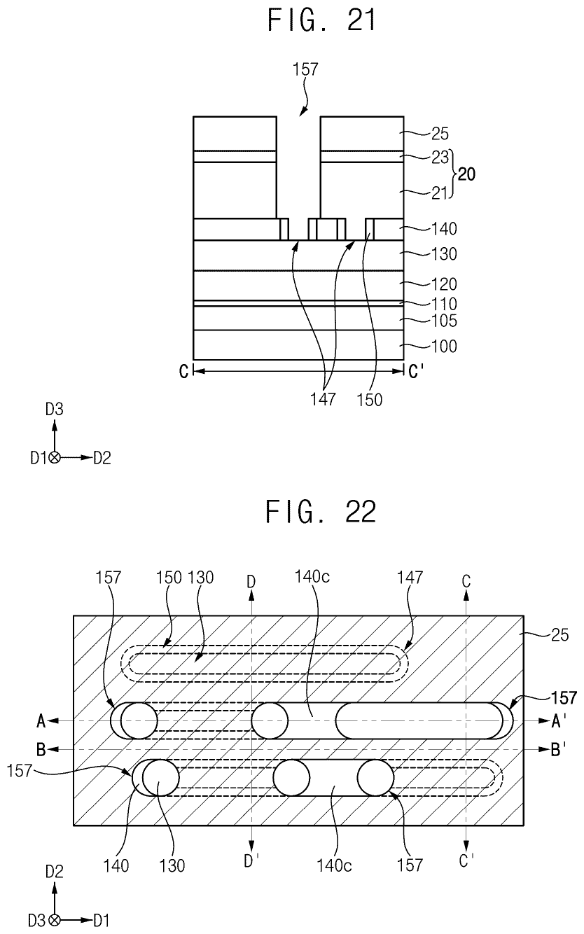

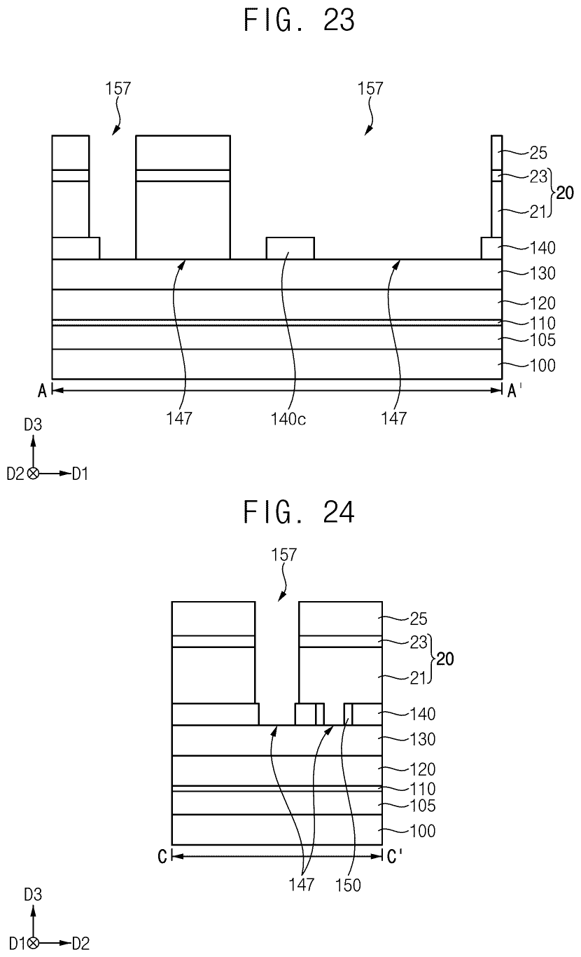

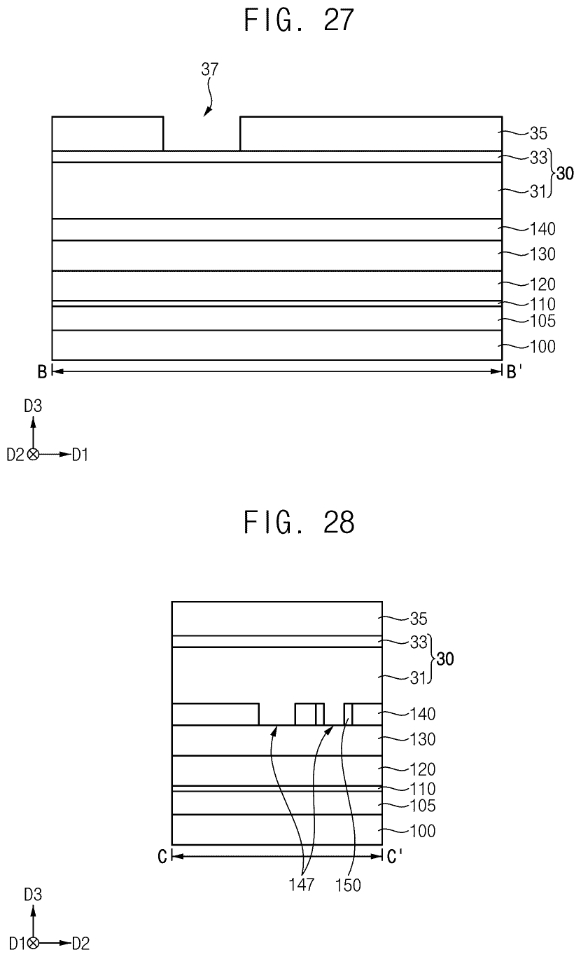

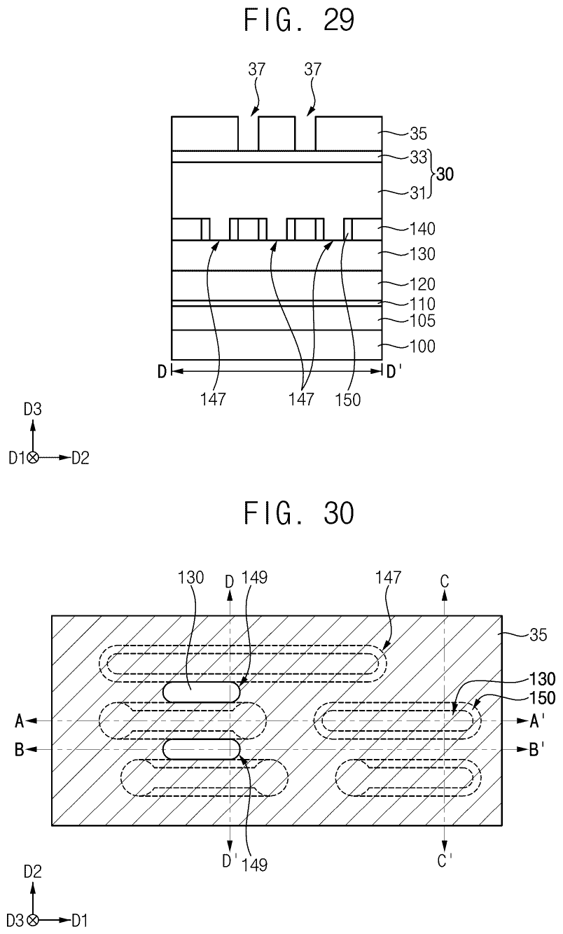

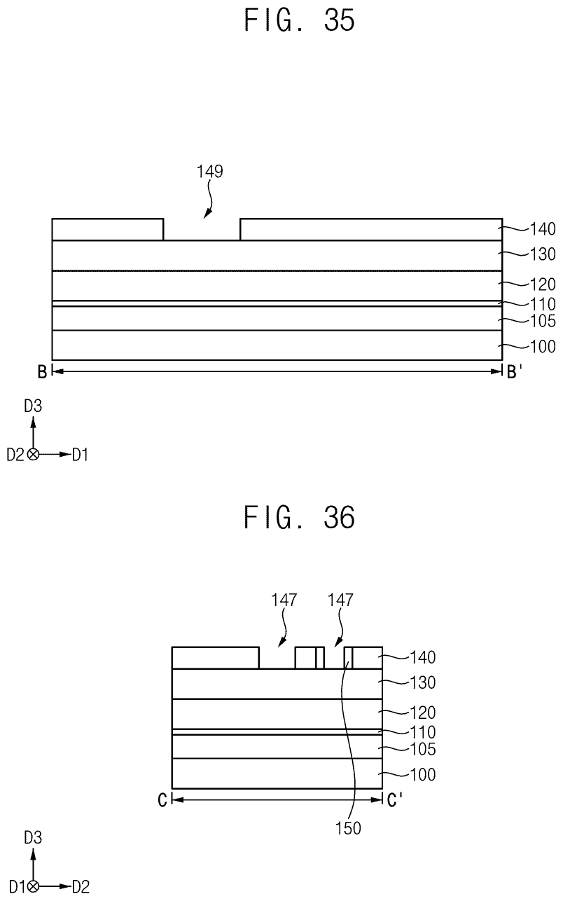

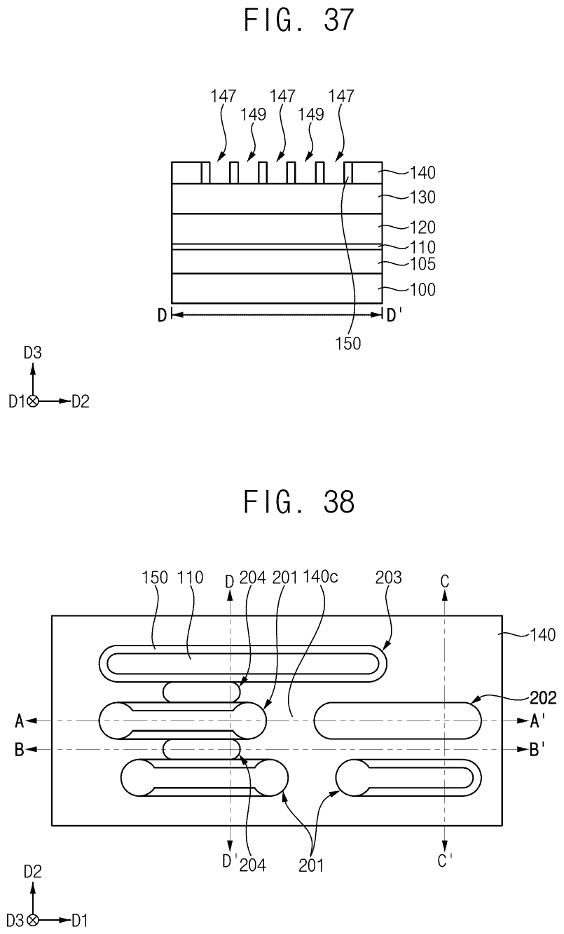

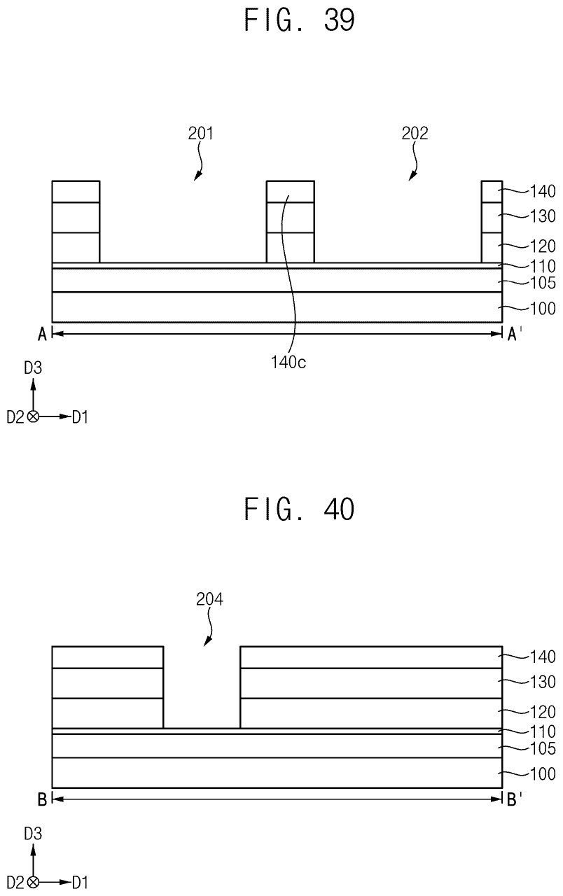

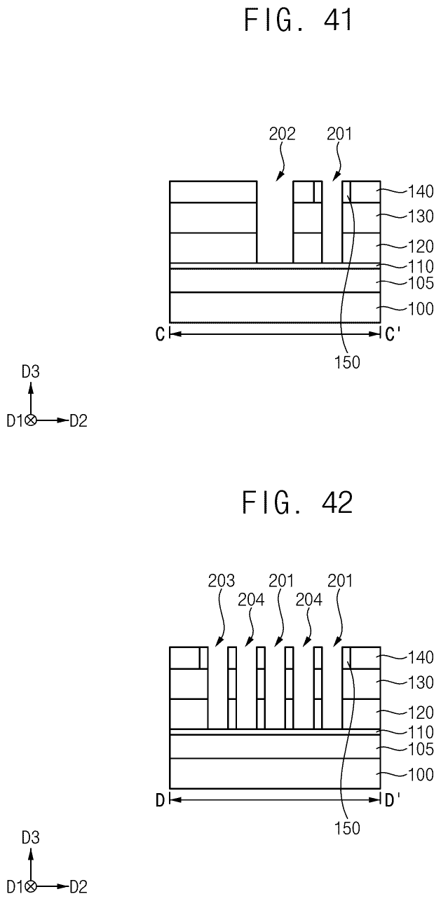

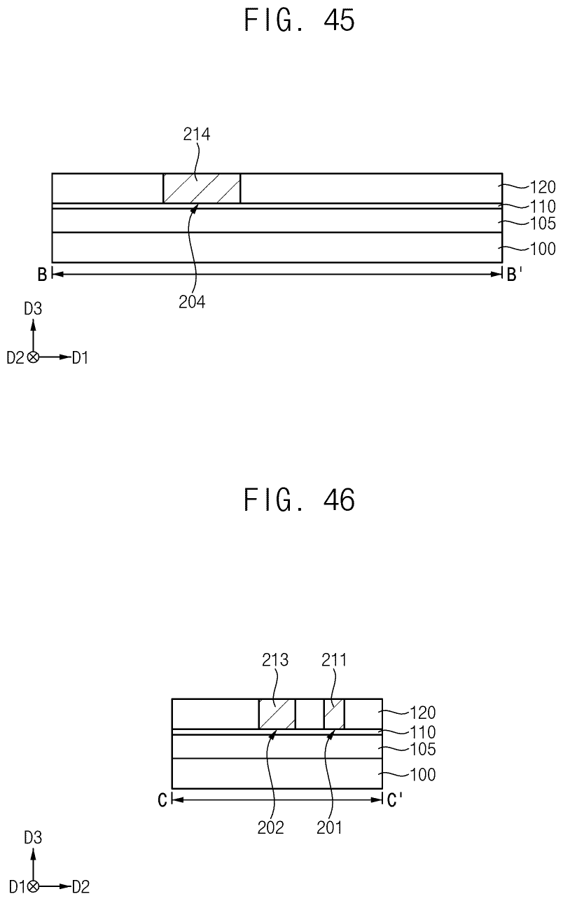

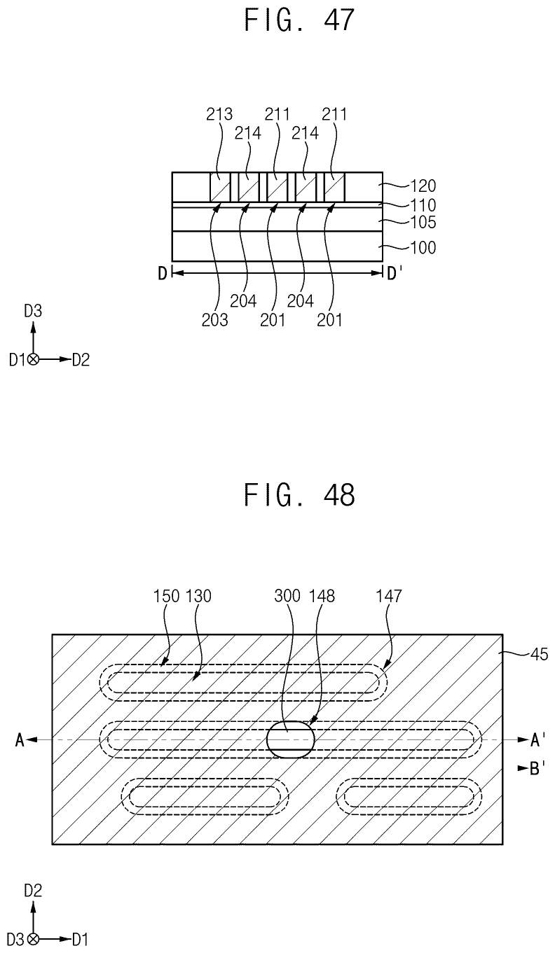

FIGS. 1 to 47 are plan views and cross-sectional views illustrating a method of manufacturing a wiring structure according to example embodiments of the present inventive concept. Specifically, FIGS. 1, 6, 10, 14, 19, 22, 25, 30, 33, 38 and 43 are the plan views, FIGS. 2, 7, 11, 15, 20, 23, 26, 34, 39 and 44 are cross-sectional views taken along lines A-A′, respectively, of corresponding plan views. FIGS. 3, 16, 27, 31, 35, 40 and 45 are cross-sectional views taken along lines B-B′, respectively, of corresponding plan views. FIGS. 4, 8, 12, 17, 21, 24, 28, 36, 41 and 46 are cross-sectional views taken along lines C-C′, respectively, of corresponding plan views, and FIGS. 5, 9, 13, 18, 29, 32, 37, 42 and 47 are cross-sectional views taken along lines D-D′, respectively, of corresponding plan views.

Referring to FIGS. 1 to 5, an insulating interlayer 105, an etch stop layer 110, an etch target layer 120, a hard mask 130 and a mandrel 140 may be sequentially formed on a substrate 100.

The substrate 100 may include a semiconductor material, e.g., silicon, germanium, silicon-germanium, etc., or a III-V group compound semiconductor, e.g., GaP, GaAs, GaSb, etc. In example embodiments of the present inventive concept, the substrate 100 may be a silicon-on-insulator (SOI) substrate or a germanium-on-insulator (GOI) substrate.

A wiring structure may be provided in the etch target layer 120. A tack structure electrically connecting the wiring structure and an active region of the substrate 100 may be provided in the insulating interlayer 105.

Each of the insulating interlayer 105 and the etch target layer 120 may include, for example, a low dielectric material such as silicon nitride (SiN), silicon oxide (SiO₂), silicon oxycarbide (SiOC), silicon oxynitride (SiON), silicon oxycarbonitride (SiOCN), silicon carbonitride (SiCN), etc. The etch stop layer 110 may include a material having an etch selectivity with respect to the etch target layer 120.

The hard mask 130 may include, for example, a metal nitride such as titanium nitride. The hard mask 130 may be formed to have a single layer; however, the present inventive concept is not limited thereto, and may be formed to have a plurality of layers including different materials with mutual selectivity.

The mandrel 140 may include, for example, amorphous silicon. The mandrel 140 may be later patterned to include second and sixth openings 147 and 149 that define positions at which wirings of the wiring structures are formed.

A first mask structure 10 and a first photoresist pattern 15 may be sequentially formed on the hard mask 130. The first mask structure 10 may include a first mold 11 and a first anti-reflection layer 13 sequentially stacked in the third direction D3.

The first mold 11 may include, for example, a carbon-containing layer such as SOH (Spin On Hardmask), silicon oxide (SiO₂), silicon nitride (SiN), etc. The first mold 11 may be formed of a single layer; however, the present inventive concept is not limited thereto, and may be formed to have a plurality of layers including different materials with mutual selectivity.

The first anti-reflection layer 13 may include, for example, titanium (Ti), titanium nitride (TiN), chromium oxide (Cr₂O₃), carbon (C), silicon nitride (SiN), silicon oxynitride (SiON), amorphous silicon, etc.

The first photoresist pattern 15 may include a first opening 17. The first opening 17 may be formed at a position corresponding to the second opening 147, which may define a position at which the wiring is formed.

In example embodiments of the present inventive concept, the first opening 17 may extend in the first direction D1, and a plurality of first openings 17 may be spaced apart from each other in the first and second directions D1 and D2. A portion of the first photoresist pattern 15 formed between the first openings 17, which are adjacent to each other in the first direction D1, may correspond to the cut-off region of the wiring that extends in the first direction D1.

Referring to FIGS. 6 to 9, the first mask structure 10 may be patterned by using the first photoresist pattern 15 including the first opening 17. The mandrel 140 may be etched by using the patterned first mask structure 10. Accordingly, a second opening 147 exposing an upper surface of the hard mask 130 may be formed at a position corresponding to the first opening 17.

In example embodiments of the present inventive concept, the second opening 147 may extend in the first direction D1, and a plurality of second openings 147 may be spaced apart from each other in the first and second directions D1 and D2. A portion of the mandrel 140 formed between the second openings 147, which are adjacent to each other in the first direction D1, (hereinafter, referred to as a cut-off mandrel 140C) may correspond to the cut-off region of the wiring that extends in the first direction D1.

Referring to FIGS. 10 to 13, the first photoresist pattern 15 and the first mask structure 10 may be removed. A spacer layer may be formed on the upper surface of the hard mask 130 that is exposed by the second opening 147. The spacer layer may also be formed on a sidewall and an upper surface of the mandrel 140, and an anisotropic etching process may be performed on the spacer layer to form a spacer 150. Accordingly, the spacer 150 may be formed along the sidewall of the mandrel 140, that is, an inner sidewall of the second opening 147.

In example embodiments of the present inventive concept, in a plan view, the spacer 150 may have a shape of an oval ring (e.g., an annular shape) in which a diameter in the first direction D1 is greater than a diameter in the second direction D2. However, the present inventive concept is not limited thereto, and in a plan view, the spacer 150 may have a shape of a rectangular ring (e.g., a rectangular annular shape) in which a length in the first direction D1 is greater than a length in the second direction D2.

In example embodiments of the present inventive concept, the spacer 150 may include a material having an etch selectivity with respect to the mandrel 140, for example, titanium oxide (TiO₂).

Referring to FIGS. 14 to 18, a second mask structure 20 and a second photoresist pattern 25 may be formed on the upper surface of the hard mask 130, which is exposed by the second opening 147, the mandrel 140 and the spacer 150. The second mask structure 20 may include a second mold 21 and a second anti-reflection layer 23 sequentially stacked in the third direction D3 on the upper surface of the hard mask 130, which is exposed by the second opening 147, the mandrel 140 and the spacer 150.

The second mold 21 and the second anti-reflection layer 23 of the second mask structure 20 may include substantially the same or similar materials as those of the first mold 11 and the first anti-reflection layer 13 of the first mask structure 10, respectively.

The second photoresist pattern 25 may include a third opening 27. A plurality of third openings 27 may be spaced apart from each other in the first and second directions D2. The third opening 27 may at least partially overlap a portion of the spacer 150 to be removed in the third direction D3.

In example embodiments of the present inventive concept, some of the third openings 27 may overlap portions of the spacers 150, which are adjacent to each other in the first direction D1, in the third direction D3. For example, some of the third openings 27 may overlap portions of the spacers 150 at a sidewall of the cut-off mandrel 140C in the third direction D3. Some others of the third openings 27 may overlap a portion of the spacer 150, which is disposed on the inner sidewall of the second opening 147, in the third direction D3. Some others of the third opening 27 may overlap the spacer 150 as a whole that is disposed on the inner sidewall of the second opening 147 in the third direction D3. However, the present inventive concept is not limited thereto, and a position of the third opening 27 may be adjusted.

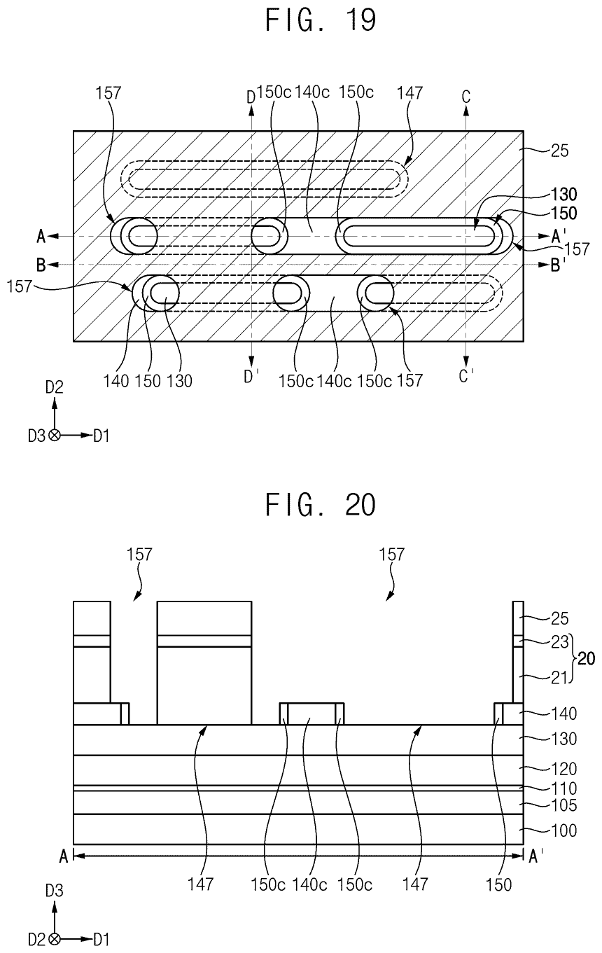

Referring to FIGS. 19 to 21, the second mask structure 20 may be patterned by using the second photoresist pattern 25 including the third opening 27. Accordingly, a fourth opening 157 may be formed to expose the portion of the spacer 150 that overlaps the third opening 27 in the third direction D3, the upper surface of the hard mask 130, and the upper surface of the mandrel 140.

Referring to FIGS. 22 to 24, the portion of the spacer 150 that is exposed by the fourth opening 157 may be selectively removed by performing a selective etching process. The mandrel 140 may include a material having an etch selectivity with respect to the spacer 150, and thus, may remain without being removed during the etching process.

Accordingly, both end portions in the first direction D1 of some of the spacers 150, which has a shape of an oval ring (e.g. an annular shape) in a plan view, may be removed, so that the spacer 150 may be divided into two spacers 150, each having a shape of a line. In addition, one of the end portions in the first direction D1 of some others of the spacers 150 may be removed, and thus, the spacer 150 may be formed to have a shape of a “U” rotated about 90 degrees in a plan view. A width in the first direction D1 of the second opening 147, in which the two spacers each having a shape of a line are provided, may be expanded by a width in the first direction D1 of the removed portion of the spacer 150. A width in the first direction D1 of the second opening 147, in which the spacer 150 having a shape of a “U” rotated about 90 degrees is provided, may be expanded by a width in the first direction D1 of the removed portion of the spacer 150.

Some of the spacers 150 may be removed as a whole. A width in the first and second directions D1 and D2 of the second opening 147 from which the spacer 150 is removed may be expanded by a width in the first and second directions D1 and D2 of the removed spacer 150.

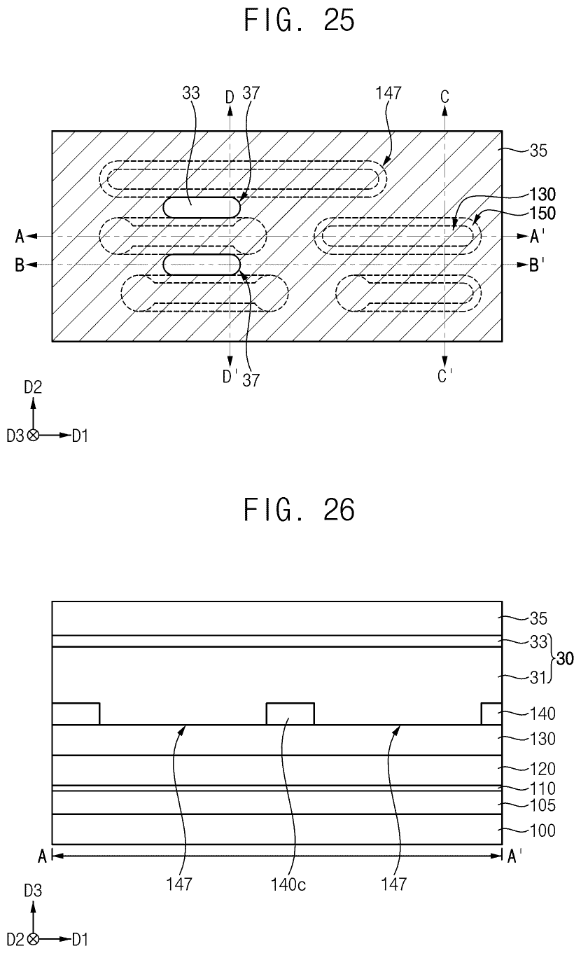

Referring to FIGS. 25 to 29, the second mask structure 20 and the second photoresist pattern 25 may be removed. A third mask structure 30 and a third photoresist pattern 35 may be sequentially formed on the hard mask 130, the mandrel 140 including the second opening 147, and the spacer 150. The third mask structure 30 may include a third mold 31 and a third anti-reflection layer 33 sequentially stacked in the third direction D3 on the hard mask 130, the mandrel 140 including the second opening 147, and the spacer 150.

The third mold 31 and the third anti-reflection layer 33 of the third mask structure 30 may include substantially the same or similar materials as those of the first mold 11 and the first anti-reflection layer 13 of the first mask structure 10, respectively.

The third photoresist pattern 35 may include a fifth opening 37. The fifth opening 37 may expose an upper surface of the third anti-reflection layer 33.

In example embodiments of the present inventive concept, the fifth opening 37 may extend in the first direction D1, and a plurality of the fifth openings 37 may be spaced apart from each other in the second directions D2. The fifth opening 37 may overlap, in the third direction D3, a portion of the mandrel 140 that is disposed between the spacers 150 that face each other in the second direction D2.

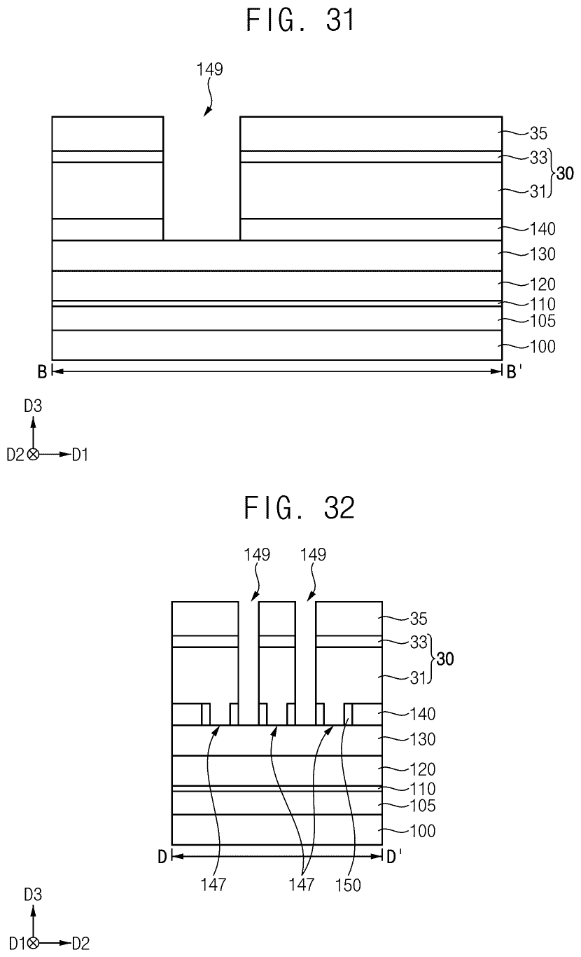

Referring to FIGS. 30 to 32, the third mask structure 30 may be patterned by using the third photoresist pattern 35 including the fifth opening 37. The portion of the mandrel 140 that overlaps the fifth opening 37 may be etched by using the patterned third mask structure 30. Accordingly, a sixth opening 149 may be formed, and the sixth opening 149 may expose the upper surface of the hard mask 130 and a sidewall of the spacer 150. The spacer 150 may include a material having an etch selectivity with respect to the mandrel 140, and thus, may remain without being removed during the etching process.

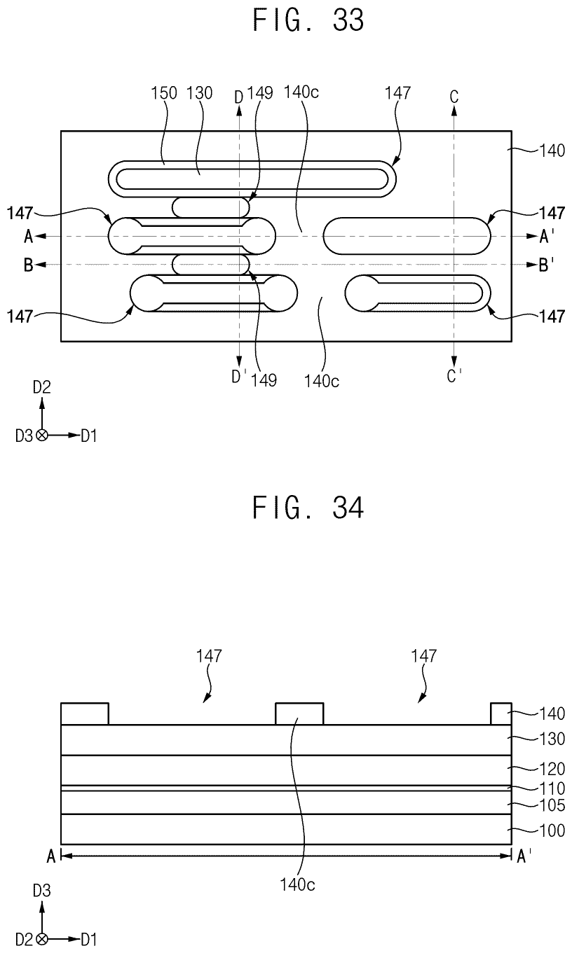

Referring to FIGS. 33 to 37, the third photoresist pattern 35 and the third mask structure 30 may be removed.

The mandrel 140 may include the second openings 147 and the sixth openings 149. The second opening 147 may extend in the first direction D1, and a plurality of second openings 147 may be spaced apart from each other in the first and second directions D1 and D2. The sixth opening 149 may extend in the first direction D1 between the second openings 147, which are adjacent to each other in the second direction D2, and a plurality of sixth openings 149 may be spaced apart from each other in the second direction D2. The second and sixth openings 147 and 149 may define positions of the wirings. Positions of the second and sixth openings 147 and 149 may be adjusted.

Referring to FIGS. 38 to 42, the mandrel 140, which includes the second and sixth openings 147 and 149, and the spacer 150, which is disposed on the inner sidewall of the second opening 147, may be used to pattern the hard mask 130, and the patterned hard mask 130 may be used to pattern the etch target layer 120.

The etch stop layer 110 may include a material having an etch selectivity with respect to the etch target layer 120, and thus, the etch stop layer 110 may serve as a reference point for completing the etching process.

The etch target layer 120 may be etched to include seventh to ninth openings 201, 202 and 203, which are formed by extending the second openings 147 in the third direction D3, and a tenth opening 204, which is formed by extending the sixth opening 149 in the third direction D3.

For example, the seventh opening 201 may be formed by expanding the second opening 147, in which the two spacers 150 each having a shape of a line or the spacer 150 having a shape of a “U” rotated about 90 degrees is provided, in the third direction D3. The eighth opening 202 may be formed by expanding the second opening 147, from which the spacer 150 is entirely removed, in the third direction D3. The ninth opening 203 may be formed by expanding the second opening 147, in which the spacer 150 having a shape of an oval ring is provided, in the third direction D3.

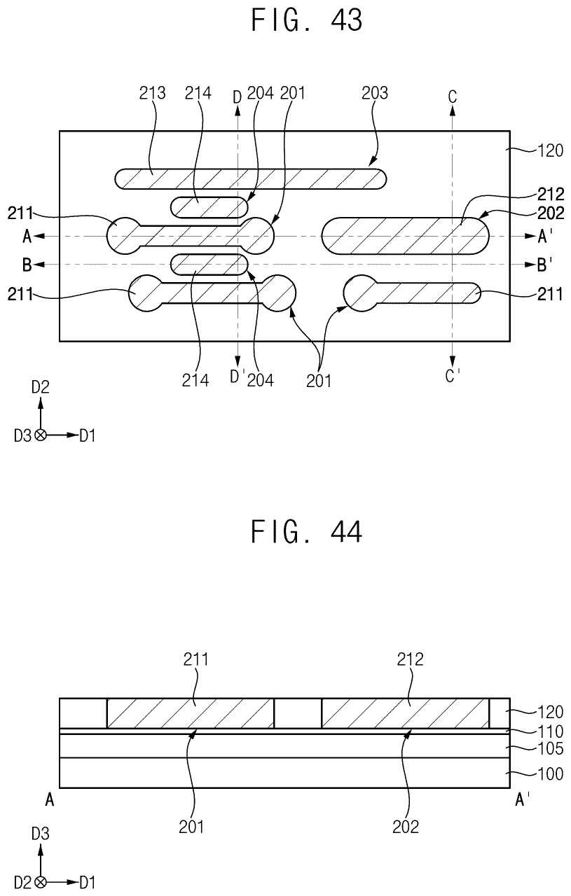

Referring to FIGS. 43 to 47, first to fourth wirings 211, 212, 213 and 214 may be formed in the seventh to tenth openings 201, 202, 203 and 204, respectively.

The first wiring 211 may be formed to include an extension portion extending in the first direction D1 and an expansion portion formed at an end portion in the first direction D1 of the extension portion. A first maximum width in the second direction D2 of the expansion portion may be greater than a first width portion in the second direction D2 of the extension.

In example embodiments of the present inventive concept, the expansion portion may be formed only at one of the end portions of the extension portion, and thus, the first wiring 211 may have a shape of a matchstick in a plan view. For example, the expansion portion may have a circular shape, and the extension portion may extend in the first direction D1 and have a curved side surface that is opposite to the expansion portion. In example embodiments of the present inventive concept, the expansion portion may be formed at both of the end portions of the extension portion. For example, the first wiring may have a shape of a dumbbell in a plan view. For example, the extension portion may extend in the first direction D1, and circular expansion portions may be provided at opposing ends of the extension portion.

In example embodiments of the present inventive concept, the first wiring 211 may extend in the first direction D1, and a plurality of first wirings 211 may be spaced apart from each other in the first and second directions D1 and D2.

A second width in the second direction D2 of the second wiring 212 may be substantially the same as the first maximum width of the expansion portion of the first wiring 211. The second width in the second direction D2 of the second wiring 212 may be substantially constant along the first direction D1 except for end portions in the first direction D1 thereof. For example, the end portions of the second wiring 212 may be curved.

In example embodiments of the present inventive concept, the second wiring 212 may extend in the first direction D1, and a plurality of second wirings 212 may be spaced apart from each other in the first and second directions D1 and D2.

A third width in the second direction D2 of the third wiring 213 may be substantially constant along the first direction D1 except for end portions in the first direction D1 thereof. For example, the end portions of the third wiring 213 may be curved.

In example embodiments of the present inventive concept, the third wiring 213 may extend in the first direction D1, and a plurality of third wirings 213 may be spaced apart from each other in the first and second directions D1 and D2.

A fourth width in the second direction D2 of the fourth wiring 214 may be substantially contact along the first direction D1 except for end portions in the first direction D1 thereof. For example, the end portions of the fourth wiring 214 may be curved.

In example embodiments of the present inventive concept, the fourth wiring 214 may extend in the first direction D1 between ones of the first to third wirings 211, 212 and 213 adjacent to each other in the second direction D2, and a plurality of fourth wirings 214 may be spaced apart from each other in the first and second directions D1 and D2. For example, fourth wirings 214 may be formed between the third wiring 213 and the first wiring 211 in the second direction D2, and may be formed between adjacent first wirings 211 in the second direction D2.

The first to fourth wirings 211, 212, 213 and 214 may together form a wiring structure.

In example embodiments of the present inventive concept, each of the first to fourth wires 211, 212, 213 and 214 may include a metal pattern and a barrier pattern covering a lower surface and a sidewall of the metal pattern. The metal pattern may include a metal such as tungsten, copper, aluminum, cobalt, molybdenum, etc., and the barrier pattern may include a metal nitride such as titanium nitride, tantalum nitride, tungsten nitride, etc.

A region between the first wirings 211, which are adjacent to each other in the first direction D1, and/or a region between the first wiring 211 and the second wiring 212, which are adjacent to each other in the first direction D1, may each be referred to as a cut-off region. A width in the first direction D1 of the cut-off region may be determined by a width in the first direction D1 of the cut-off mandrel 140C from which the cut-off spacer 150C is removed.

In the method of manufacturing the wiring structure, the mandrel 140 including the second opening 147 may formed, the spacer 150 may be formed on the inner sidewall of the second opening 147, and the cut-off spacer 150C at the sidewall of the cut-off mandrel 140C, which is formed between the second openings 147 adjacent to each other in the first direction D1, may be removed through the fourth opening 157.

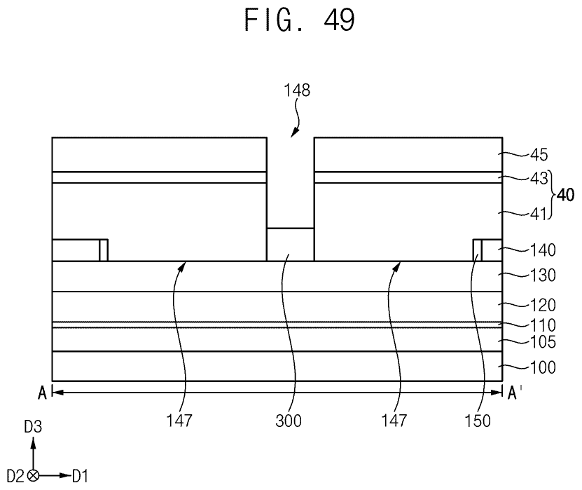

Referring to FIGS. 48 and 49, in a comparative example, unlike the processes illustrated with reference to FIGS. 14 to 24, a fourth mask structure 40 including a fourth mold 41 and a fourth anti-reflection layer 43, and a fourth photoresist pattern 45 including a hole-type eleventh opening that partially overlaps the second opening 147 may be sequentially formed on the mandrel 140 and the spacer 150. The fourth mask structure 40 may patterned by using the fourth photoresist pattern 45 including the eleventh opening to form a twelfth opening 148 that exposes the upper surface of the hard mask 130, and a cut-off pattern 300 may be formed within the twelfth opening 148. Manufacturing of the wiring structure may be completed by performing processes substantially the same as or similar to the processes illustrated with reference to FIGS. 25 to 47. For example, the mandrel 140 including the second and sixth openings 147 and 149 and the cut-off pattern 300 that divides the second opening 147 in the first direction D1 may define the positions of the wirings of the wiring structures, and in particular, the cut-off region may be defined by the cut-off pattern 300.

In the method of manufacturing the wiring structure according to a comparative example, adjusting a width in the first direction D1 of the cut-off region after forming the mandrel 140 and the spacer 150 may be difficult. Accordingly, the cut-off pattern 300 may be formed in the twelfth opening 148, but the hole-type twelfth opening 148 may have a relatively small width in the first direction D1. Thus, there is a high possibility that defects such as an overlay may occur during the process for forming the cut-off pattern 300 in the twelfth opening 148. In addition, defects may also occur due to the cut-off pattern 300 itself.

However, the method of manufacturing the wiring structure according to example embodiments of the present inventive concept may further include steps of removing the cut-off spacer 150C that are disposed on the sidewall of the cut-off mandrel 140C. Accordingly, distance between the second openings 147 that are adjacent to each other in the first direction D1 may be reduced by the width in the first direction D1 of the removed cut-off spacer 150C. Hence, distance in the first direction D1 between the first wires 211 formed in the seventh openings 201 which are formed by extending the second openings 147 in the third direction D3, that is, the width in the first direction D1 of the cut-off region, may decrease. Accordingly, the degree of integration of the semiconductor device including the wiring structure may be increased.

In addition, the width in the first direction D1 of the cut-off region may be sufficiently reduced, and thus, the process of forming the cut-off pattern 300 may be omitted. In addition, the line-type fourth opening 157 may have a greater width in the first direction D1 than that of the eleventh opening and twelfth opening 148 which are hole-type openings, and hence, the occurrence of defects may be reduced. Accordingly, reliability of the wiring structure may be increased.

Additionally, not only the cut-off spacer 150C disposed on the inner sidewall of the end portion in the first direction D1 of the second opening 147, but also the portion of the spacer 150 that is at the inner sidewall in the second direction D2 of the second opening 147 may be additionally removed to expand the width in the second direction D2 of the second opening 147. Accordingly, the width in the second direction D2 of the second wiring 212 may be increased, and thus, resistance of the wiring structure including the second wiring 212 may be reduced.

While the present inventive concept has been described with reference to example embodiments thereof, it will be understood by those of ordinary skill in the art that various changes in form and details may be made thereto without departing from the spirit and scope of the present inventive concept.

What is claimed is:

1. A wiring structure comprising:
a first wiring disposed on a substrate, wherein the first wiring includes a first extension portion that extends in a first direction and has a first width in a second direction, and a first expansion portion that is formed at a first end portion of end portions, in the first direction, of the first extension portion and has a first maximum width in the second direction, wherein the first maximum width is larger than the first width, wherein the first direction is substantially parallel to an upper surface of the substrate, and the second direction is substantially parallel to the upper surface of the substrate and crosses the first direction; and
a second wiring disposed on the substrate, wherein the second wiring extends in the first direction and faces the first expansion portion of the first wiring in the first direction, wherein a first end portion of end portions, in the first direction, of the second wiring facing the first expansion portion has a second maximum width in the second direction, wherein the second maximum width is substantially the same as the first maximum width.

2. The wiring structure of claim 1, wherein the first expansion portion of the first wiring is disposed at only the first end portion of the end portions of the first extension portion of the first wiring.

3. The wiring structure of claim 2, wherein the first expansion portion has a circular shape, and a second end portion of the end portions of the first extension portion has a curved surface.

4. The wiring structure of claim 1, wherein the first wiring further includes a second expansion portion that is formed at a second end portion of the end portions, in the first direction, of the first extension portion and has the first maximum width in the second direction.

5. The wiring structure of claim 4, wherein each of the first expansion portion and the second expansion portion has a circular shape.

6. The wiring structure of claim 1, wherein a width in the second direction of the second wiring is substantially constant at the second maximum width.

7. The wiring structure of claim 1, wherein the second wiring includes a second extension portion and a second expansion portion, wherein the second extension portion extends in the first direction and has a second width in the second direction, wherein the second expansion portion is formed at a first end portion of end portions, in the first direction, of the second extension portion and has the second maximum width, wherein the first end portion of the second extension portion corresponds to the first end portion of the second wiring, and wherein the second maximum width is greater than the second width.

8. The wiring structure of claim 7, wherein the second expansion portion of the second wiring is disposed at only the first end portion of end portions, in the first direction, of the second extension portion of the second wiring.

9. The wiring structure of claim 8, wherein the second expansion portion has a circular shape, and a second end portion of the end portions of the second extension portion has a curved surface.

10. The wiring structure of claim 7, wherein the second wiring further includes a third expansion portion that is formed at a second end portion of the end portions, in the first direction, of the second extension portion and has the second maximum width in the second direction.

11. The wiring structure of claim 10, wherein each of the second expansion portion and the third expansion portion has a circular shape.

12. A wiring structure comprising:
a wiring including:
an extension portion disposed on a substrate, wherein the extension portion extends in a first direction, and the extension portion has a first width in a second direction, wherein the first direction is substantially parallel to an upper surface of the substrate, and the second direction is substantially parallel to the upper surface of the substrate and crosses the first direction; and
expansion portions disposed on the substrate, wherein the expansion portions are disposed at both of end portions, in the first direction, of the extension portion, and the expansion portion has a first maximum width in the second direction, wherein the first maximum width is larger than the first width.

13. The wiring structure of claim 12, wherein each of the expansion portions has a circular shape.

14. A wiring structure comprising:
first wirings disposed on a substrate, wherein the first wirings are spaced apart from each other in a second direction, wherein each of the first wirings includes a first extension portion that extends in a first direction and has a first width in the second direction, and a first expansion portion that is formed at a first end portion of end portions, in the first direction, of the first extension portion and has a first maximum width in the second direction, wherein the first maximum width is larger than the first width, wherein the first direction is substantially parallel to an upper surface of the substrate, and the second direction is substantially parallel to the upper surface of the substrate and crosses the first direction;
second wirings disposed on the substrate, wherein the second wirings are spaced apart from each other in the second direction, wherein each of the second wirings extends in the first direction and faces the first expansion portion of the corresponding one of the first wirings in the first direction, and a first end portion of end portions, in the first direction, of at least one of the second wirings facing the first expansion portion of the corresponding one of the first wirings has a second maximum width in the second direction, wherein the second maximum width is substantially the same as the first maximum width; and
third wirings disposed on the substrate, wherein each of the third wirings extends in the first direction between ones of the first and second wirings adjacent to each other in the second direction, wherein the third wirings are spaced apart from each other in the second direction, and wherein each of the third wirings has a third width in the second direction.

15. The wiring structure of claim 14, wherein the first expansion portion of a first wiring of the first wirings is disposed at only the first end portion of the end portions of the first extension portion of the first wiring, and the first expansion portion has a circular shape.

16. The wiring structure of claim 14, wherein a first wiring of the first wirings further includes a second expansion portion that is formed at a second end portion of the end portions, in the first direction, of the first extension portion, wherein the second expansion portion has the first maximum width in the second direction, and wherein each of the first expansion portion and the second expansion portion has a circular shape.

17. The wiring structure of claim 14, wherein a width in the second direction of the second wiring is substantially constant at the second maximum width.

18. The wiring structure of claim 14, wherein a second wiring of the second wirings includes a second extension portion and a second expansion portion, wherein the second extension portion extends in the first direction and has a second width in the second direction, wherein the second expansion portion is formed at a first end portion of end portions, in the first direction, of the second extension portion and has the second maximum width, wherein the first end portion of the second extension portion corresponds to the first end portion of the second wiring, and wherein the second maximum width is larger than the second width.

19. The wiring structure of claim 18, wherein the second expansion portion of the second wiring is disposed at only the first end portion of end portions, in the first direction, of the second extension portion of the second wiring, and the second expansion portion has a circular shape.

20. The wiring structure of claim 18, wherein the second wiring of the second wirings further includes a third expansion portion that is formed at a second end portion of the end portions, in the first direction, of the second extension portion of the second wiring, wherein the third expansion portion has the second maximum width in the second direction, and wherein each of the second expansion portion and the third expansion portion has a circular shape.
